(19) United States
(12) Patent Application Publication
(10) Pub. No.: US 2021/0040601 A1
(43) Pub. Date: Feb. 11, 2021

(54) Sputtering Target and Method for Producing Sputtering Target

(71) Applicant: JX Nippon Mining & Metals Corporation, Tokyo (JP)

(72) Inventors: Keijiro Sugimoto, Ibaraki (JP); Shuhei Murata, Ibaraki (JP)

(21) Appl. No.: 16/979,697

(22) PCT Filed: Mar. 12, 2019
(86) PCT No.: PCT/JP2019/010094

§ 371 Date: Sep. 10, 2020

(30) Foreign Application Priority Data
Mar. 13, 2018 (JP) 2018-045836

(51) Int. Cl. C23C 14/34; B22F 3/15

(52) U.S. Cl. CPC C23C 14/3414; B22F 2304/10; B22F 2301/20; B22F 3/15

(57) ABSTRACT

Provided is a sputtering target having a molybdenum content of 99.99% by mass or more, a relative density of 98% or more, and an average crystal grain diameter of 400 μm or less.

### FIELD OF THE INVENTION

This specification discloses arts relating to a sputtering target and a method for producing a sputtering target.

### BACKGROUND OF THE INVENTION

Recently, ultra-high integration of LSIs has progressed, and the use of a material having lower electric resistivity as an electrode material or a wiring material has been considered. Under such circumstances, high-purity tungsten has been used as the electrode material or the wiring material, because the high-purity tungsten has characteristics such as relatively low resistivity, and good thermal and chemical stabilities.

By the way, for production of the electrode material or the wiring material, a thin film is generally formed by a sputtering method using a sputtering target. So, there is a need for a sputtering target composed of high-purity and high-density tungsten for the above electrode material and wiring material containing high-purity tungsten.

As such a technique, Patent Literatures 1 and 2 propose “a tungsten sintered compact sputtering target, wherein the purity of the tungsten is 5N (99.999%) or more, and a content of impurity carbon in the tungsten is 3 wtppm or less”. According to the “tungsten sintered compact sputtering target”, “electric resistance of the tungsten film can be stably decreased”.

Although it is not related to the above-mentioned tungsten sputtering target, Patent Literature 3 discloses “a method for producing a high-purity molybdenum target for LSI electrodes, the target having a purity of 99.999% or more, an alkali metal content of 100 ppb or less and a radioactive element content of 10 ppb or less, the method comprising: dissolving metallic molybdenum or a molybdenum compound to produce a molybdenum-containing aqueous solution; purifying the aqueous solution, and then crystallizing a molybdenum-containing crystal; subjecting the crystal to solid-liquid separation, washing, drying and reduction with heating to prepare high-purity molybdenum powder; and subjecting the high-purity molybdenum powder to molding under pressure and sintering; and then melting the high-purity molybdenum powder by an electron beam to provide a high-purity molybdenum ingot; and subjecting the ingot to plastic working and machining”.

### CITATION LIST

### Patent Literatures

[Patent Literature 1] Japanese Patent No. 5944482 B

[Patent Literature 2] US 2015/0023837 A1

[Patent Literature 3] Japanese Patent Application Publication No. H04-218912 A

### SUMMARY OF THE INVENTION

However, the high-purity tungsten film as described above has a risk that cannot meet future demands for further lower resistance. Therefore, there is a need for finding promising alternatives to tungsten.

In this regard, the molybdenum film may achieve a sufficiently low electric resistance value. However, the “high-purity molybdenum target for LSI electrodes” disclosed in Patent Literature 3 has a higher generation rate of particles during sputtering, causing a problem that a material yield is decreased.

To solve the problems as described above, this specification proposes a sputtering target mainly containing molybdenum and capable of effectively decreasing particles during sputtering, and a method for producing the sputtering target.

The sputtering target disclosed in this specification has a molybdenum content of 99.99% by mass or more, a relative density of 98% or more, and an average crystal grain diameter of 400 μm or less.

Further, the method for producing a sputtering target disclosed in this specification is a method for producing the sputtering target, the method comprising the steps of: preparing molybdenum powder; subjecting the molybdenum powder to hot pressing by applying a load to the molybdenum powder at a temperature of 1350° C. to 1500° C.; and subjecting a formed compact obtained by the hot pressing to hot isostatic pressing at a temperature of 1300° C. to 1850° C.

According to the sputtering target and the method for producing the sputtering target as described above, the sputtering target mainly contains molybdenum and can effectively decrease particles during sputtering, and such a sputtering target can be effectively produced.

### DETAILED DESCRIPTION OF THE INVENTION

Embodiments of the inventions disclosed in this specification will be described below.

A sputtering target according to an embodiment of the present invention has a molybdenum content of 99.99% by mass or more, a relative density of 98% or more, and an average crystal grain diameter of 400 μm or less. In addition to these, the sputtering target preferably has a radiation dose of 0.03 cph/cm² or less.

Conventionally, a sputtering method using a sputtering target made of high-purity tungsten was employed to produce an electrode material and a wiring material for highly integrated LSIs. However, the resulting tungsten film might not be able to meet lower resistance demands for which further development is expected.

However, as a result of studies for film-forming characteristics of metals having higher melting points, the present inventors have found that a thin film made of molybdenum, one of the metals having higher melting points, could achieve a lower resistance value than that of a thin film made of tungsten.

Furthermore, as a result of intensive studies for a sputtering target capable of forming the thin film made of molybdenum as described above, the present inventors have found that according to a certain sputtering target produced by a certain production method, a film can be formed that can achieve an even lower resistance value and can be suitably used for semiconductor applications. It has been found that such a sputtering target can effectively decrease a generation rate of particles during sputtering, and also decrease the possibility of malfunction of an electronic device formed with the resulting thin film.

Such a sputtering target and its production method will be described below in detail.

### Composition

The sputtering target of this embodiment is made of high-purity molybdenum of 4N or more, which contains 99.99% by mass or more of molybdenum. A higher purity of molybdenum will significantly decrease the generation rate of particles, while a lower purity of molybdenum will tend to increase the number of particles. Therefore, the higher purity of molybdenum is more preferable in terms of a decrease in particles. From this viewpoint, the content of molybdenum in the sputtering target is preferably 99.999% by mass or more (i.e., 5N or more).

The purity as described above means one which excludes an inseparable homologous element. That is, the inseparable homologous element is tungsten, and the purity as used herein is defined as a proportion of the content of molybdenum in the contents of all metal elements other than elements less than the detection lower limit and tungsten. The content of molybdenum is calculated based on measurement by glow discharge mass spectrometry (GDMS).

### Relative Density

In an embodiment of the present invention, the sputtering target has a relative density of 98% or more. As the relative density is higher, the particles are decreased. However, a lower relative density will tend to increase the particles. From this point of view, the relative density is preferably 99% or more, and more preferably 99.5% or more.

The relative density of the sputtering target is represented by the following equation: relative density=(measured density/theoretical density)×100 (%). In the equation, the measured density is density of the sputtering target measured by the Archimedes method using pure water as a solvent, and the theoretical density is theoretical density when assuming that the content of molybdenum is 100%.

### Crystal Grain Diameter

For a crystal grain diameter of molybdenum contained in the sputtering target, a higher crystal grain diameter tends to increase the particles, while a lower crystal grain diameter tends to decrease the particles.

Therefore, the average crystal grain diameter of molybdenum in the sputtering target is 400 μm or less, and preferably 200 μm or less. Although there is no inconvenience caused by an excessively low average crystal grain diameter of molybdenum, the average crystal grain diameter may be, for example, 15 μm or more, and typically 40 μm or more.

The average crystal grain diameter is determined by observing a target surface with an optical microscope, drawing straight lines on the resulting structure photograph until the number of particles is N≥200, and calculating L/N from the number of particles present on the straight lines (N≥200) and the total length (L) of the straight lines. The method for measuring the average crystal grain diameter is in accordance with the cutting method defined in JIS G 0551.

### Radiation Dose

The sputtering target has a radiation dose of 0.03 cph/cm² or less. A higher radiation dose will increase the possibility of malfunction of an electronic device having the thin film of molybdenum formed by using the sputtering target, while a lower radiation dose will decrease the possibility of malfunction of such an electronic device. Therefore, the radiation dose of the sputtering target is preferably 0.02 cph/cm² or less, and more preferably 0.01 cph/cm² or less.

The above radiation dose is measured using LACS-4000 M from Sumika Chemical Analysis Service, Ltd., under conditions of P-10 gas (Ar—CH₄ 10%), a flow rate of 100 ml/min, a measurement time of 99 kr, a measurement area of 203 cm³, and a counting efficiency of 80%.

### Production Method

An example of a method for producing the sputtering target as described above can include powder metallurgy which subjects certain molybdenum powder to a combination of hot pressing (HP) with hot isostatic pressing (HIP).

First, molybdenum powder is prepared as a raw material. The molybdenum powder preferably has a grain diameter in a range of from 0.1 μm to 10 μm, an average grain diameter of from 1 μm to 5 μm, and a purity of molybdenum of 4N or more. An excessively high grain diameter of the molybdenum powder may decrease the density. An excessively low grain diameter may result in bulky grains, which may increase the difficulty of handling and impair productivity (i.e., it is difficult to fill molds such as hot presses with the bulky grains, so that the number of products per one run may decrease). When the purity of the molybdenum powder is lower, the molybdenum content of the sputtering target to be produced is decreased. Therefore, it is preferable to use the molybdenum powder having a molybdenum purity of 5N or more. Further, it is also preferable to use the molybdenum powder of 5N or more as a raw material, in order to decrease the radiation dose of the produced sputtering target.

Next, in the hot pressing step, the molybdenum powder is filled in a die or other predetermined mold, and a predetermined load is applied while heating the die and maintaining it at a predetermined temperature.

Here, the load is applied while maintaining a temperature of 1350° C. to 1500° C. as the highest reaching temperature of the raw material. If the temperature at this time is lower, it cannot provide a sufficiently high relative density of the sputtering target. On the other hand, if the temperature is higher, there is a concern that the grain diameter will be increased to increase the particles. Therefore, the temperature during hot pressing is from 1350° C. to 1500° C.

Further, the time for maintaining the above temperature is preferably 60 minutes to 300 minutes. If the maintaining time is too short, there is a concern that the density will be decreased, and if it is too long, the grain diameter may be increased.

The magnitude of the load to be applied at this time is preferably from 150 kg/cm² to 300 kg/cm², and more preferably from 200 kg/cm² to 300 kg/cm². If the load is too low, the density may be decreased. In addition, there is no particular inconvenience due to the excessive load. If equipment such as dies can be withstood, an increase in the load will lead to higher density. However, in general, the upper limit would often be about 300 kg/cm².

In order to decrease a difference between the set temperature and the actual temperature during heating at the time of hot pressing, for example, when the temperature is increased, it is preferable to maintain a temperature range of from 800° C. to 1200° C. for 30 minutes as the temperature reaches that range.

The formed compact obtained in the hot pressing step is then subjected to the hot isostatic pressing. This can allow the produced sputtering target to have higher density.

In the hot isostatic pressing step, typically, a load of 1300 kg/cm² to 2000 kg/cm² is applied at a temperature of 1300° C. to 1850° C. for 60 minutes to 300 minutes. If such conditions of the temperature, load and time are not satisfied, there is a disadvantage that the density becomes low. Therefore, during the hot isostatic pressing, it is more preferable that the temperature is from 1400° C. to 1850° C., the load is from 1500 kg/cm² to 1900 kg/cm², and the time is from 60 minutes to 300 minutes.

The sintered body obtained by the hot isostatic pressing may optionally be subjected to grinding or other shape processing to produce a sputtering target having a predetermined dimension and shape.

The sputtering target thus produced has a lower generation rate of particles during sputtering, and a lower radiation dose, thereby resulting in a lower possibility of malfunction of an electronic device having a thin film of molybdenum formed by the sputtering target.

The present invention is not limited to the embodiments as described above, and each element of the embodiments can be modified and embodied without departing from the spirit of the invention. For example, various embodiments can be constructed by appropriately combining a plurality of elements included in each embodiment. It is also possible to delete some elements from all the elements of the embodiments.

### EXAMPLES

Next, the sputtering target as described above was experimentally produced and the effects thereof were confirmed, as described below. However, the descriptions herein are merely for illustrative and are not intended to be limited thereto.

Molybdenum powder having an average grain diameter of 5 μm and a predetermined purity was filled in a carbon die and subjected to hot pressing at the predetermined temperature under a load of 300 kgf/cm². The formed compact thus obtained was subjected to hot isostatic pressing at the predetermined temperature by applying a load of 1800 kgf/cm² to obtain a sintered body. The sintered body was then subjected to shape processing to produce a sputtering target having a diameter of 164 mm and a thickness of 5 mm.

In each of Examples 1 to 7 and Comparative Examples 1 and 2, a sputtering target was produced by the same method, with the exception that the highest reaching temperature of the hot pressing (HP) and the highest reaching temperature of the hot isostatic pressing (HIP) were changed as shown in Table 1. In each of Comparative Examples 3 and 4, a sputtering target was produced by hot rolling after the hot pressing, in place of the hot pressing and the hot isostatic pressing as described above. For the hot rolling, in Comparative Example 3, the formed compact was passed through rolls five times at a temperature of 1200° C., and in Comparative Example 4, the formed compact was passed through the rolls six times at a temperature of 1200° C., to roll each compact to a thickness of 10 mm, and finish it by the subsequent shape processing so as to have the above dimensions.

For each sputtering target produced as described above, the purity, average crystal grain diameter (grain diameter), relative density (density), and radiation dose were measured according to the measurement methods as described above. The results are shown in Table 1. For the measurement of the purity, the content of molybdenum was measured by glow discharge mass spectrometry (GDMS) using ELEMENT GD from Thermo Fisher, and the carbon concentration was measured using LECO carbon analyzer (CSLS 600) and the oxygen concentration was measured using an oxygen/nitrogen simultaneous analysis apparatus (TC-600) from LECO, by an inert gas melting method.

The purity as shown in Table 1 means the purity (% by mass) of molybdenum in the sputtering target. The purity of the sputtering target was substantially the same as that of the molybdenum powder as the raw material.

Further, using each of the above sputtering targets, sputtering was carried out on a silicon substrate in an atmosphere filled with an Ar gas to form a molybdenum film. Specifically, the sputtering target was attached to a magnetron sputtering device (C-3010 sputtering system from CANON ANELVA CORPORATION), and sputtering was carried out. The sputtering conditions were an input power of 0.5 kW, and an Ar gas pressure of 0.5 Pa, and a pre-sputtering of 1.7 kWhr was carried out, and a thin film having a film thickness of 30 nm was then formed on a silicon substrate having a diameter of 4 inches. The number of particles having a particle diameter of 0.07 μm or more, which deposited onto the substrate, was measured by a surface foreign matter inspection device (Candela CS920, from KLA-Tencor). The results are also shown in Table 1.

TABLE 1

| | | Production | Grain | | | | Radiation | |
|---|---|---|---|---|---|---|---|---|
| | Purity | Method | Diameter | HP Condition | HIP Condition | Density | Dose | Particles |
| Example 1 | 99.999% | HP + HIP | 45 | 1500° C. × 3 h | 1370° C. × 4 h | 99.5% | 0.01 | 10 |
| Example 2 | 99.999% | HP + HIP | 225 | 1500° C. × 3 h | 1850° C. × 2 h | 99.9% | 0.01 | 15 |
| Example 3 | 99.999% | HP + HIP | 40 | 1400° C. × 3 h | 1370° C. × 4 h | 98.9% | 0.01 | 20 |
| Example 4 | 99.99% | HP + HIP | 20 | 1500° C. × 3 h | 1370° C. × 4 h | 99.2% | 0.01 | 20 |
| Example 5 | 99.999% | HP + HIP | 30 | 1350° C. × 3 h | 1370° C. × 4 h | 98.3% | 0.01 | 29 |
| Example 6 | 99.999% | HP + HIP | 360 | 1500° C. × 3 h | 1850° C. × 4 h | 99.8% | 0.01 | 22 |
| Example 7 | 99.99% | HP + HIP | 340 | 1500° C. × 3 h | 1850° C. × 4 h | 99.9% | 0.01 | 33 |
| Comparative | 99.999% | HP + HIP | 30 | 1300° C. × 3 h | 1370° C. × 4 h | 97.5% | 0.01 | 49 |
| Example 1 | | | | | | | | |
| Comparative | 99.9% | HP + HIP | 19 | 1500° C. × 3 h | 1370° C. × 4 h | 99.6% | 0.05 | 38 |
| Example 2 | | | | | | | | |
| Comparative | 99.95% | HP + Rolling | 500 | 1500° C. × 3 h | — | 100.0% | 0.05 | 60 |
| Example 3 | | | | | | | | |
| Comparative | 99.999% | HP + Rolling | 480 | 1500° C. × 3 h | — | 100.0% | 0.01 | 58 |
| Example 4 | | | | | | | | |

In each of Examples 1 to 7, the production by hot pressing and hot isostatic pressing under predetermined conditions provided the sputtering target having the higher purity, the higher relative density, and the lower average crystal grain diameter. This could lead to effectively decreased particles during sputtering.

On the other hand, in Comparative Example 1, the relative density was lower due to the lower hot pressing temperature. In Comparative Example 2, the purity of the sputtering target was lower due to the lower purity of the raw material molybdenum powder. In Comparative Example 3, the average crystal grain diameter was increased, due to the lower purity and production by rolling in place of the hot isostatic pressing. In each of Comparative Examples 2 and 3, the radiation dose was increased due to the influence of the raw material molybdenum powder.

In Comparative Example 4, the production by rolling in place of the hot isostatic pressing provided the higher average crystal grain diameter.

As a result, the particles were increased in all Comparative Examples 1 to 4.

1. A sputtering target, the sputtering target having a molybdenum content of 99.99% by mass or more, a relative density of 98% or more, and an average crystal grain diameter of 400 μm or less.

2. (canceled)

3. The sputtering target according to claim 1, wherein the radiation dose is 0.02 cph/cm² or less.

4. The sputtering target according to claim 1, wherein the molybdenum content is 99.999% by mass or more.

5. The sputtering target according to claim 1, wherein the relative density is 99% or more.

6. The sputtering target according to claim 1, wherein the average crystal grain diameter is 200 μm or less.

7. A method for producing the sputtering target according to claim 1, the method comprising the steps of:
preparing molybdenum powder;
subjecting the molybdenum powder to hot pressing by applying a load to the molybdenum powder at a temperature of 1350° C. to 1500° C.; and
subjecting a formed compact obtained by the hot pressing to hot isostatic pressing at a temperature of 1300° C. to 1850° C.

8. The method according to claim 7, wherein the load applied to the molybdenum powder is from 200 kg/cm² to 300 kg/cm² in the step of subjecting the molybdenum powder to the hot pressing.

9. The method according to claim 7, wherein the hot pressing is carried out for 60 minutes to 300 minutes.

10. The method according to claim 7, wherein a load applied to the formed compact is from 1300 kg/cm² to 2000 kg/cm² in the step of subjecting the formed compact to the hot isostatic pressing.

11. The method according to claim 7, wherein the hot isostatic pressing is carried out for 60 minutes to 300 minutes.

12. The method according to claim 7, wherein the step of preparing the molybdenum powder comprises preparing molybdenum powder having a purity of 4N or more and an average grain diameter of from 1 μm to 5 μm.
